(19) United States
(12) Patent Application Publication
(10) Pub. No.: US 2003/0174473 A1
(43) Pub. Date: Sep. 18, 2003

(54) Limited movement system for motor switch mounted thermo-protector

(76) Inventors: William R. Lewis, Hazelwood, MO (US); Philip S. Johnson, Granite City, IL (US)

Correspondence Address: Joseph M. Rolnicki, Thompson Coburn LLP, Suite 3500, One US Bank Plaza, St. Louis, MO, 63101-9928, US

(21) Appl. No.: 10/210,615

(22) Filed: Jul. 31, 2002

Related U.S. Application Data
(63) Continuation-in-part of application No. 10/099,297, filed on Mar. 15, 2002.

(51) Int. Cl. H05K 5/00; H05K 5/04; H05K 5/06

(52) U.S. Cl. 361/752

(57) ABSTRACT

A mounting clip that attaches a circuit component to an electrical device attenuates vibration of the circuit component as the electrical device is operated. The mounting clip is designed for a thermo-protector of an electric motor and removably attaches the thermo-protector to a switch housing of the electric motor. The thermo-protector is connected in the circuit of the electric motor and wiring of the electric motor that communicates with the thermo-protector is attached to the mounting clip. The mounting clip is provided with a pair of resilient, J-shaped fingers and the component wiring is pressed between the fingers and the mounting clip to restrain movement of the wiring relative to the component.

This patent application is a continuation-in-part application of patent application Ser. No. 10/099,297 titled “LIMITED MOVEMENT SYSTEM FOR MOTOR SWITCH MOUNTED THERMO-PROTECTOR”, which was filed on Mar. 15, 2002 and is currently pending.

### BACKGROUND OF THE INVENTION

(1) Field of the Invention

The present invention pertains to an improved mounting clip that attaches a circuit component to an electrical device and attenuates vibration of the circuit component and its wiring as the electrical device is operated. More specifically, the present invention pertains to a mounting clip for a thermo-protector that removably attaches the thermo-protector to a switch housing of an electric motor. The thermo-protector is connected to the stator windings of the electric motor. The wiring of the electric motor connected to the thermo-protector is attached to the mounting clip by circular wire management hooks. The mounting clip is provided with a spring mechanism that engages an abutment provided on the switch housing and biases the mounting clip and the attached thermo-protector and thermo-protector wiring away from the switch housing and thereby attenuates vibration of the thermo-protector and its wiring.

(2) Description of the Related Art

Electrical devices, and in particular electric motors, are often provided with thermo-protectors that are connected to the stator winding of the electric motor. The thermo-protector limits the temperature of the electric motor wiring during operation of the electric motor. In this manner the typical thermo-protector protects the wiring of the electric motor, as well as other circuit components of the electric motor, from damage due to excessive heat generated by the current passing through the motor windings.

FIG. 1 shows one illustrative environment of a prior art electric motor 10 having a thermo-protector 12 as a circuit component in the winding of the motor. Because the electric motor 10 and the thermo-protector 12 shown in FIG. 1 are known, they are represented schematically in the drawing figure and only a portion of the motor is shown.

The motor 10 includes a stator comprised of stator laminate plates 14 and magnetic wiring wrapped around the poles of the stator (not shown). The end turns 16 of the stator magnetic wiring 16 are shown projecting from one end of the stack of stator laminate plates 14. An end shield or end cage 18 is also shown in FIG. 1 and a switch housing 22 is shown attached to the end cage.

The circuit component or thermo-protector 12 of the illustrative example has a narrow, box shaped configuration. The thermo-protector is shown connected to a lead 26 of the stator winding. The winding lead 26 is connected to a terminal 28 of the circuit component. A second terminal 32 of the circuit component is connected by a length of wire 34 to a terminal 36 of the switch housing. Additional stator winding leads 38 are connected to other terminals 42 of the switch housing.

The thermo-protector is releasably attached to the switch housing 22 by a mounting clip 44. The mounting clip 44 has an elongate, generally rectangular base 46 and an elongate, generally rectangular support panel 48. The base and support panel intersect each other and give the mounting clip a cross configuration. A pair of resilient flanges 52 project from opposite ends of the base to one side of the base. An attachment hook 54 projects from the opposite side of the base. Each of the flanges 52 have tabs 56 projecting from the flange distal ends. The pair of tabs 56 project toward each other.

The prior art mounting clip 44 is typically constructed of plastic, giving the pair of base flanges 52 a flexibility or resilience. The opposed tabs 56 and the resilience of the base flanges 52 enable the mounting clip 44 to be releasably attached to the circuit component 12 by passing the flanges 52 over opposite sides of the component, with the flange tabs 56 engaging in slots in opposite sides of the circuit component. In this manner, the mounting clip 44 is removably attached to the circuit component 12, meaning that the clip is attached to the component without separate fasteners. By being removably attached to the component, the mounting clip 44 can be easily manually attached and removed from the circuit component 12 without separate fasteners and without damaging parts of the mounting clip.

The support panel 48 of the mounting clip has a pair of wiring clasp assemblies 58 that project outwardly from one side of the panel. The stator winding leads 26, 38 are pressed between the opposed clasps of the two clasp assemblies 58 to removably attach the wiring leads to the support panel of the mounting clip 44 as shown in FIG. 1. As can best be seen in FIG. 4, each of the clasp assemblies 58 is comprised of a pair of opposed clothespin type prongs 60 that project outwardly from the support panel 48 of the clip. In use of the clasp assemblies 58, the stator winding leads 26, 38 would be pressed downwardly toward the support panel 48 between the opposed prongs 60 of each clasp assembly. Pressing the stator winding leads 26, 38 between the pairs of opposed prongs 60 would cause the prongs to resiliently flex away from each other as the wiring leads were positioned between the prongs and then resiliently move back to their at rest positions shown in FIG. 4, thereby clasping the wiring leads between the opposed prongs. However, in order to make the prongs 60 sufficiently resilient to deflect from each other and accept the wiring leads between the prongs, it was necessary that the thickness of the prongs be reduced. This would often cause one or both of the prongs 60 of an opposed pair to break at its connection to the support panel 48 as the stator winding leads 26, 38 were pressed between the opposed pair of prongs. To overcome this problem, the prongs 60 were dimensioned with a greater thickness to resist their breaking. However, this reduced the resiliency of the prongs and made it difficult to manually press the stator winding leads 26, 38 between the prongs. Also, pressing the stator winding leads 26, 38 between the more rigid prongs 60 would at times cause damage to the insulation of the winding leads which potentially would cause the winding leads to short circuit.

In attaching the circuit component 12 to the switch housing 22 employing the mounting clip 44 of the prior art, the clip 44 is first removably attached to one side of the thermo-protector circuit component 12. The clip is positioned with its flanges 52 adjacent opposite sides of the circuit component 12 and then is pressed onto the component. The clip flanges 52 are caused to flex away from each other and the tabs 56 of the flanges pass over the opposite sides of the circuit component until they engage in the slots (not shown) in the opposite sides of the component. This removably attaches the mounting clip 44 to the circuit component 12.

The clip and component are then assembled to the switch housing 22. The switch housing 22 is provided with a receptacle 62 having an interior volume 64 that is configured to receive at least a portion of the circuit component 12 and the mounting clip 44 attached to the component. A side wall 66 of the receptacle surrounds the interior volume 64. An edge 68 of the receptacle side wall defines a receptacle opening through which the circuit component and attached mounting clip are inserted. The receptacle side wall has a smaller side wall opening 72 at the back of the receptacle interior volume 64 from the receptacle opening. As the component 12 and attached mounting clip 44 are inserted through the receptacle opening and into the receptacle interior volume 64, the attachment hook 54 projecting from the mounting clip base 46 engages in the side wall opening 72 and thereby releasably attaches the circuit component 12 and the mounting clip 44 to the switch housing 22. The stator winding leads are connected to the clasp assemblies 58 as shown in FIG. 1.

The mounting clip 44 of the prior art described above functions well in providing a removable attachment between the circuit component or thermo-protector 12 and a housing of the electric motor 10, specifically the switch housing 22. The releasable attachment of the mounting clip 44 to the circuit component 12 and to the switch housing receptacle 62 enables a quick and easy attachment of the circuit component to the electric motor without the need for separate fasteners. However, during use of the electric motor 10, problems associated with the use of the mounting clip 44 were discovered.

As stated earlier, pressing the stator winding leads 26, 38 between the opposed prongs 60 of each clasp assembly 58 would at times cause the thinner, more resilient prongs to break. When the opposed prongs 60 of the clasp assemblies 58 were made thicker and more rigid to prevent their breaking, the reduced resiliency of the prongs made it difficult to insert the stator winding leads 26, 38 between the opposed prongs 60 of each clasp assembly 58. In addition, the more rigid prongs would at times produced cuts or scraps in the stator winding leads insulation presenting the potential problem of a short circuit between the winding leads.

Furthermore, because the mounting clip 44 is releasably attached or snapped to the circuit component 12 and is then releasably attached or snapped to the receptacle 62 of the switch housing 22, during operation of the motor 10 vibrations from the motor were transmitted to the mounting clip. The vibrations of the mounting clip were also transferred to the stator winding leads 26, 38 held in the clasp assemblies 58 of the mounting clip. The vibration of these leads caused them to rub across each other which at times caused the insulation of the winding leads to wear away, resulting in a short circuit between the leads.

What is needed to overcome the problem with the prior art mounting clip is a stator winding clasp that is easy to attach the winding leads to without the potential for breaking, and a means of attenuating the vibration of the clip when the electrical device is operated which in turn will attenuate the vibration of the circuit components and the rubbing together of the circuit component wiring.

### SUMMARY OF THE INVENTION

The present invention provides a system of limiting the movement of a circuit component mounted to the housing of an electrical device and the relative rubbing and wearing away of the circuit component wiring insulation. In the illustrative embodiment of the invention, the system limits the movement of a thermo-protector relative to a switch housing of an electric motor. However, the system is equally well suited for use in other environments. The system also employs a modified stator winding clasp assembly that resists breakage yet is sufficiently resilient to easily accept the stator winding leads without damaging their insulation.

The invention basically provides a modification to the prior art mounting clip and prior art switch housing described above that attenuates vibration of the thermo-protector mounted to the switch housing and the rubbing together of the circuit component wiring leads.

The mounting clip of the invention is basically constructed as the prior art mounting clip with improvements. A slot is provided in the support panel of the mounting clip. The slot is positioned adjacent a corner of the rectangular shaped support panel and as it extends into the support panel, it sets apart a portion of the mounting clip panel between the slot and the edge of the support panel. This set apart portion of the support panel forms a narrow, elongate spring arm extending along the peripheral edge of the panel.

The switch housing of the invention is modified with an abutment on the edge of the switch housing receptacle wall adjacent the receptacle opening. The abutment projects outwardly, away from the receptacle wall edge.

The mounting clip is removably attached to the thermo-protector circuit component in the same manner as the prior art mounting clip. The mounting clip is then attached to the receptacle of the switch housing in the same manner as the prior art mounting clip and switch housing. However, the abutment on the receptacle wall of the switch housing and the spring arm on the mounting clip are positioned so that a distal end of the spring arm will come into engagement with the abutment as the mounting clip and attached circuit component are inserted into the receptacle of the switch housing. As the mounting clip and attached circuit component are attached to the receptacle of the switch housing, the spring arm is resiliently flexed by the abutment. Thus, with the mounting clip and circuit component removably attached to the switch housing, the resilience of the spring arm exerts a force on the abutment of the switch housing that biases the mounting clip and attached circuit component away from the switch housing receptacle. This biasing force exerted by the spring arm attenuates vibration of the mounting clip and the rubbing together of the attached circuit component wiring leads during operation of the motor. In this manner, the apparatus of the invention attenuates the wearing away of the insulation on the wiring leads of the thermo-protector circuit component and overcomes the disadvantages associated with the prior art mounting clip and switch housing.

In addition, the pairs of opposed prongs of the prior art mounting clip clasp assemblies are each replaced by a single, generally circular finger that projects from the support panel of the clip. Each finger has a larger cross-sectional area where the finger attaches to the support panel. The cross-sectional area of the each finger gradually decreases as the finger extends from its end attached to the support panel through a curved, generally circular configuration of the finger to its distal free end. The free end of each finger is spaced from the support panel and the spacing, together with the resiliency of the finger, allows the stator winding leads to be passed through the spacing and inserted between the finger and the support panel to clasp the winding leads to the clip.

### BRIEF DESCRIPTION OF THE DRAWINGS

Further features of the invention are revealed in the following detailed description of the preferred embodiment of the invention and in the drawing figures wherein:

FIG. 1 is a partial side view of a prior art electrical device, or electric motor, showing the prior art mounting clip removably attaching a thermo-protector circuit component to a switch housing of the motor;

FIG. 2 is a plan view of the prior art mounting clip;

FIG. 3 is a plan view of the opposite side of the prior art mounting clip shown in FIG. 2;

FIG. 4 is a side view of the mounting clip shown in FIG. 2;

FIG. 5 is a plan view of the prior art switch housing;

FIG. 6 is a plan view of the mounting clip of the invention removably attached to the thermo-protector circuit component;

FIG. 7 is a side view of the mounting clip and circuit component shown in FIG. 6;

FIG. 8 is a partial view similar to that of FIG. 1 but showing the mounting clip and switch housing of the invention assembled to each other;

FIG. 9 is a plan view of the modified switch housing of the invention;

FIG. 10 is a plan view of the modified mounting clip of the invention;

FIG. 11 is a plan view of the opposite side of the mounting clip shown in FIG. 10; and

FIG. 12 is a side view of the mounting clip shown in FIG. 10.

### DETAILED DESCRIPTION OF THE PREFERRED EMBODIMENT

The novel system of the invention that attenuates the vibration and rubbing together of electric wiring leads of a circuit component mounted to a housing of an electrical device is basically comprised of a modified mounting clip 82 shown in FIGS. 10-12 and a modified switch housing 84 shown in FIGS. 8 and 9. In the illustrative example of the invention to follow, the system is described as limiting the movement of a thermo-protector circuit component relative to a switch housing of an electric motor and thereby attenuating rubbing together of the components wiring leads. However, the mounting clip 82 and its associated switch housing 84 may be employed to removably attach other types of circuit components to other types of electrical devices. In the preferred embodiment, both the mounting clip 82 and switch housing 84 are constructed of a plastic, however other similar types of materials may also be employed.

The mounting clip 82 has a construction that is very similar to that of the prior art mounting clip 44. It is also provided with an elongate, generally rectangular base 86 and an elongate, generally rectangular support panel 88. The base and support panel also intersect with each other and give the mounting clip a cross configuration. A pair of resilient flanges 92 project from opposite ends of the base and extend to one side of the base as shown in FIG. 12. An attachment hook 94 projects outwardly from the opposite side of the base. Each of the flanges 92 are provided with projecting tabs 96 at their distal ends. The tabs 96 project toward each other as shown in FIG. 12.

The modified mounting clip 82 differs from the prior art mounting clip in that it is also provided with an elongate slot 102 that extends into the support panel 88 from an edge 104 of the panel. The slot 102 is formed in the panel adjacent a corner of the panel and sets apart a portion 106 of the panel as a narrow, elongate spring arm mechanism projecting outwardly from and integral with the panel. The rectangular configuration of the support panel 88 and the configuration of the slot 102 extending along a straight line through the panel gives the spring arm 106 a narrow, straight configuration that cantilevers outwardly from the support panel.

The modified switch housing 84 of the invention is also constructed in a similar manner to that of the prior art switch housing 22. The view of the housing 84 shown in FIG. 9 is turned 90 degrees about a horizontal axis from the position of the prior art housing 22 shown in FIG. 8. The switch housing includes a receptacle 112 that has an interior volume 114 that is dimensioned and configured to receive at least a portion of the thermo-protector circuit component 12 and the modified mounting clip 82 attached to the component. A receptacle side wall 116 extends at least partially around the receptacle interior volume 114. An outward edge 118 of the receptacle side wall 116 defines the receptacle opening to the receptacle interior volume. An attachment hook opening 122 is provided through the receptacle side wall 116 at the back of the receptacle interior volume 114 opposite the receptacle opening.

The modified switch housing 84 differs from the prior art switch housing 22 by also including an abutment 124 that projects outwardly from the side wall edge 118 of the receptacle. The abutment 124 projects in a direction that is opposite to the direction of insertion of the clip 82 and thermo-protector 12 when assembling the clip and protector to the switch housing. The abutment 124 also projects in a direction that is transverse to the direction that the spring arm mechanism 106 projects from the support panel 88 when the mounting clip 82 is removably attached to the switch housing 84.

The modified mounting clip 82 differs from the prior art mounting clip in that it is also provided with a pair of resilient, curved fingers 132 that project outwardly from the support panel 88. Each one of the resilient fingers 132 replaces a pair of opposed prongs 60 of the wiring clasp assembly 58 of the prior art. The configurations of each of the resilient fingers 132 is best seen in FIG. 12. Each of the fingers has a J-shaped configuration with a base 134 of each finger connecting it to the support panel 88. From the base 134 each finger extends outwardly from the support base 88 through its generally J-shaped configuration to a distal end 136 of the finger that is spaced from the support panel 88. The spacing 138 between the finger distal end 136 and the clip support panel 88 is provided for insertion of the stator winding leads 26, 38 through the spacing 138 and into the void 140 surrounded by the length 142 of the resilient finger. Because the lengths of the resilient fingers 132 are longer than the lengths of the prongs 60 of the prior art clasp assemblies 58, they have a greater resiliency than the prongs. The increased resiliency of the curved fingers 132 makes it easier to deflect the fingers away from the clip support panel 88 and insert the stator winding leads 26 through the spacings 138 and into the voids 140 surrounded by the fingers. In addition, the finger base 134 that attaches each finger to the support panel 88 has an enlarged cross-sectional area than the remainder of the length 142 of the finger. This gives the finger greater strength at its connection to the support panel 88 which resists breaking of the finger from the support panel as the stator winding leads are inserted through the spacing 138 and into the void 140 of the finger. With this construction of each resilient, curved finger 132 of the mounting clip, the problems associated with the prior art wiring clasp assemblies are avoided.

The modified mounting clip 82 is attached to the thermo-protector 12 in the same manner as the prior art mounting clip. The clip 82 is positioned with its flanges 92 adjacent opposite sides of the thermo-protector 12 and then is pressed onto the protector. The clip flanges 92 are caused to resiliently flex away from each other and the flange tabs 96 pass over the opposite sides of the protector until they engage in slots (not shown) in the opposite sides of the protector. This removably attaches the mounting clip 82 to the protector 12 in the relative positions of the clip and protector shown in FIGS. 6 and 7.

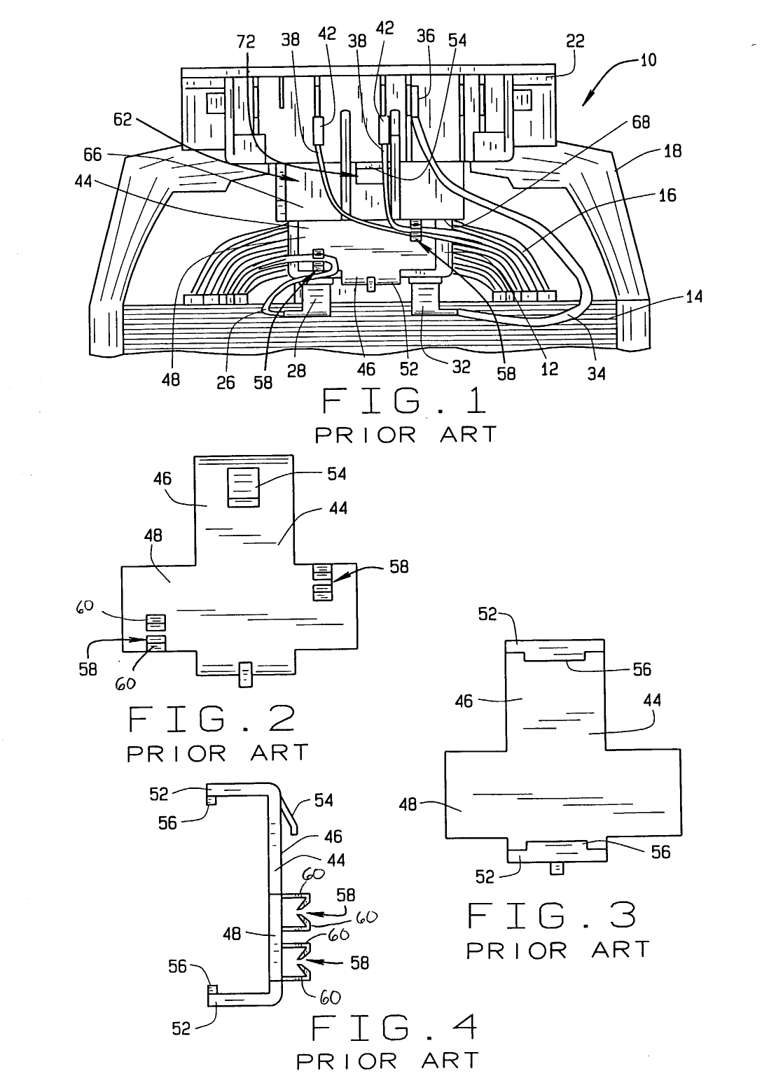

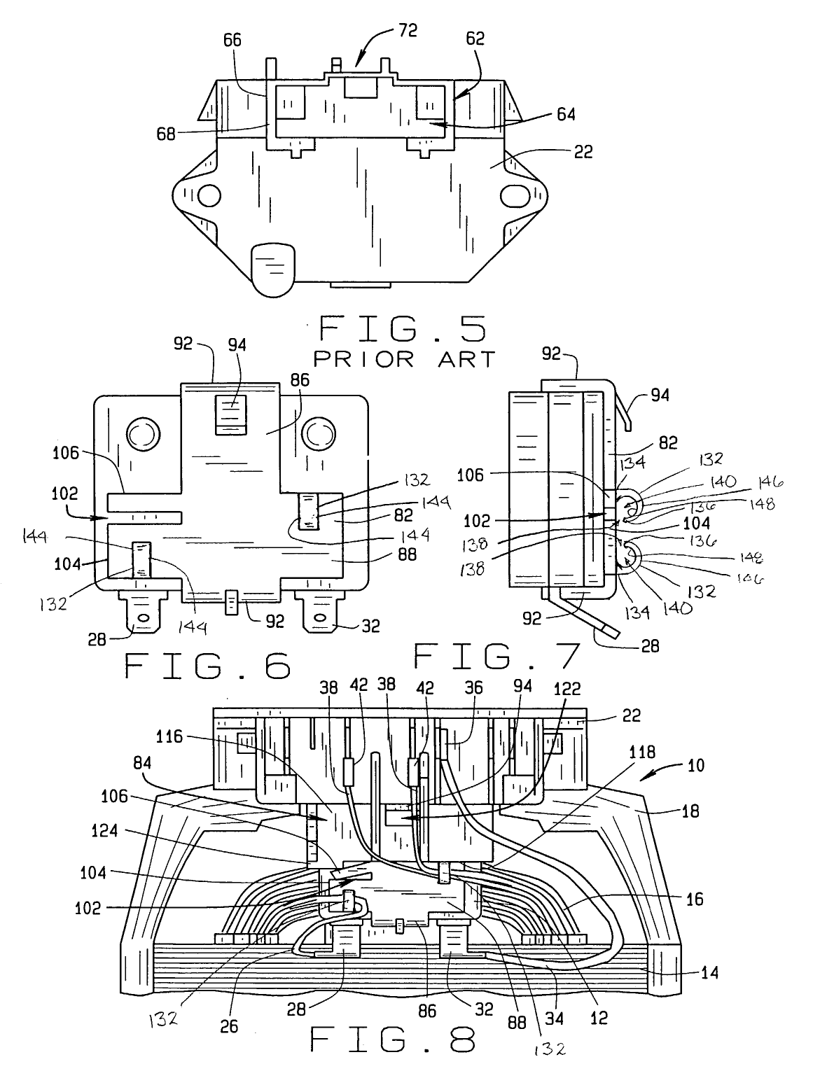

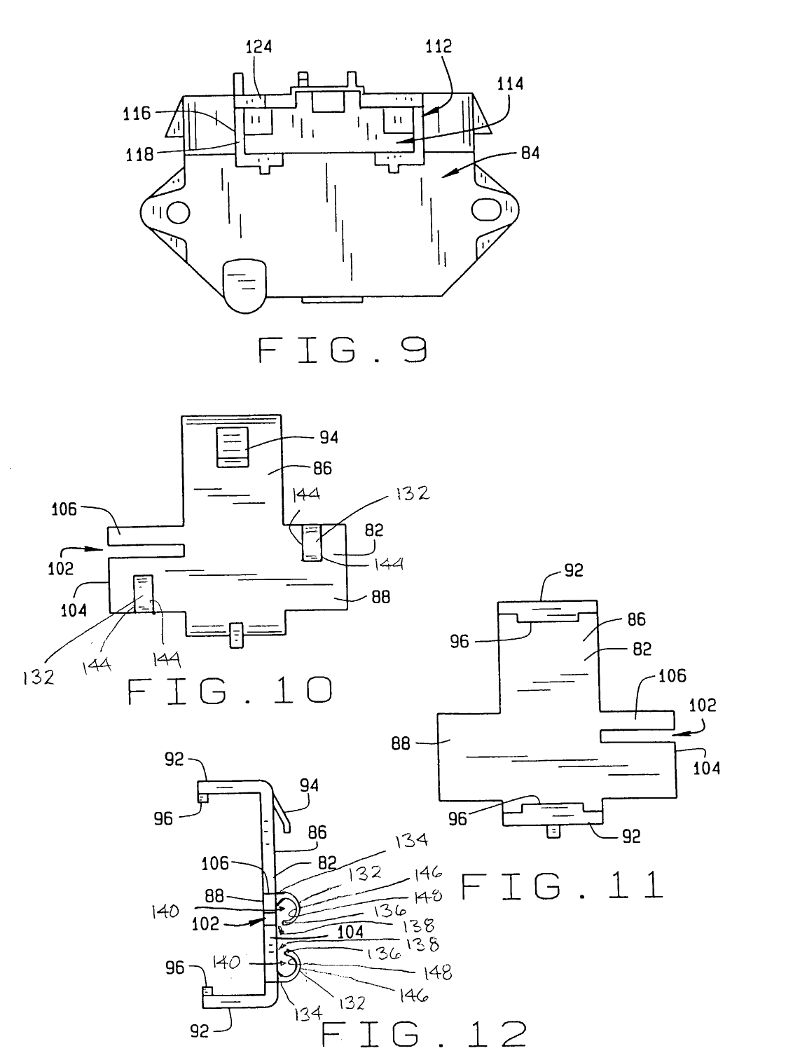

The clip 82 and protector 12 are then removably attached to the modified switch housing 84. With the orientation of the switch housing 84 shown in FIG. 9, the mounting clip 82 with the removably attached protector 12 is positioned so that the clip is above the protector and the attachment hook end of the clip is first inserted through the receptacle opening defined by the side wall edge 118. FIG. 8 shows the switch housing of FIG. 8 turned 90 degrees about a horizontal line. The positioning of the switch housing 84 shown relative to the electric motor 10 in FIG. 8 is the same orientation of the prior art switch housing 22 shown relative to the motor 10 in FIG. 1. As the thermo-protector 12 and the removably attached mounting clip 84 are inserted through the receptacle opening and into the interior volume 114 of the receptacle, the attachment hook 94 projecting from the clip base 86 engages in the attachment hook opening 122 in the receptacle side wall. This releasably attaches the thermo-protector 12 and the modified mounting clip 82 to the switch housing 84. However, as the thermo-protector 12 and modified mounting clip 82 are inserted into the receptacle, the abutment 124 on the receptacle side wall edge 118 engages with the spring arm 106 on the mounting clip. As the mounting clip 82 and thermo-protector 12 are continued to be inserted into the receptacle volume 114, the spring arm 106 is resiliently flexed by the abutment 124. Thus, with the mounting clip 82 and the thermo-protector 12 removably attached to the modified switch housing 84 in their relative positions shown in FIG. 8, the resilience of the spring arm 106 exerts a force on the abutment 124 of the switch housing that biases the mounting clip 82 and the attached thermo-protector 12 away from the switch housing receptacle 112.

The wiring leads 26, 38 of the circuit component 12 are next inserted into the resilient curved fingers 132. Due to the increased lengths of each finger between its base 134 attached to the support panel 88 and its distal end 136, the cross-sectional area of each finger can be enlarged without appreciably detracting from the resiliency of the finger. Thus, each finger 132 is easily deflected away from the support panel 88 as the wiring leads 26, 38 are passed through the spacing 138 of the finger and into the void 140 surrounded by the finger. The resiliency of the finger securely holds the wiring leads to the support panel 88. Because the lengths of the fingers increase their resiliency, the potential for cutting or scraping the insulation of the wiring leads as the leads are inserted into the fingers is reduced. In addition, because the cross-sectional areas of the fingers is increased, in particular where the base 134 of each finger attaches to the support panel 88, the potential for breaking the fingers as the wiring leads are attached to the support panel 88 by the fingers is reduced.

The spring force exerted by the spring arm 106 against the housing abutment 124 attenuates vibration of the mounting clip 82 and the rubbing together of the attached circuit component wiring leads 26, 38 that could wear away the insulation of the wiring leads and short circuit the motor. In this manner, the apparatus of the invention overcomes the disadvantages associated with the prior art mounting clip and switch housing.

While the present invention has been described by reference to a specific embodiment, it should be understood that modifications and variations of the invention may be constructed without departing form the scope of the invention defined in the following claims.

What is claimed:

1. An apparatus for mounting a circuit component to an electrical device, the apparatus comprising:
a circuit component attached to the electrical device, the circuit component having at least one wiring lead extending from the circuit component to the electrical device;
a resilient finger attached to the circuit component, the finger having a length that extends around the at least one wiring lead to a free distal end of the finger and restrains the at least one wiring lead from movement.

2. The apparatus of claim 1, further comprising:
the length of the finger having a J-shape.

3. The apparatus of claim 2, further comprising:
the at least one wiring lead being one of a plurality of wiring leads extending from the circuit component; and
the resilient finger J-shaped length extending around the plurality of wiring leads.

4. The apparatus of claim 2, further comprising:
the resilient finger being one of a pair of resilient fingers attached to the circuit component with each fingers having a length with a J-shape that extends around the plurality of wiring leads.

5. The apparatus of claim 2, further comprising:
the resilient finger having a base proximate the circuit component with the J-shaped length of the finger extending from the base, and cross-sectional areas of the finger length being largest at the finger base.

6. The apparatus of claim 2, further comprising:
the resilient finger having a pair of side surfaces that are parallel to each other and a curved interior surface and a curved exterior surface that extend the length of the finger between the pair of side surfaces.

7. The apparatus of claim 2, further comprising:
the distal end of the finger being spaced a first distance from the circuit component and the length of the finger extending to a second distance away from the circuit component as the length of the finger extends around the at least one wiring lead, the second distance being larger than the first distance.

8. The apparatus of claim 2, further comprising:
a mounting clip removably attached to the circuit component, the mounting clip being removably attached to the electrical device and thereby attaching the circuit component to the electrical device; and
the resilient finger being integral with the mounting clip.

9. The apparatus of claim 8, further comprising:
the resilient finger having a base that joins the finger to the mounting clip with the J-shaped length of the finger extending from the base to the finger distal end, and the finger having a cross-sectional area at the base that is a largest cross-sectional area of the finger length.

10. The apparatus of claim 8, further comprising:
the J-shaped length of the finger extending away from the mounting clip and curving back toward the mounting clip as the length of the finger extends from the mounting clip to the finger distal end.

11. The apparatus of claim 10, further comprising:
a spacing between the finger distal end and the mounting clip spacing the finger distal end a first distance from the mounting clip and the length of the finger extending away from the mounting clip a second distance that is larger than the first distance.

12. The apparatus of claim 8, further comprising:
the distal end of the finger being spaced a first distance from the mounting clip and the length of the finger extending to a second distance away from the mounting clip as the length of the finger extends around the at least one wiring lead, the second distance being larger than the first distance.

13. The apparatus of claim 8, further comprising:
the resilient finger being one of a pair of resilient fingers each having a same configuration and each being integral with the mounting clip.

14. An apparatus for restraining wiring leads of an electric motor circuit component, the apparatus comprising:
an electric motor having a stator with stator windings;
a circuit component attached to the electric motor, the circuit component having a wiring lead that extends between the circuit component and the stator windings; and,
a resilient finger attached to the circuit component, the resilient finger having a length that extends around the wiring lead to a free distal end of the finger, the length of the finger solely restraining movement of the wiring lead relative to the circuit component.

15. The apparatus of claim 14, further comprising:
the wiring lead being one of a plurality of wiring leads extending between the circuit component and the stator windings; and
the resilient finger being one of a pair of resilient fingers that both extend around the plurality of wiring leads and restrain movement of the plurality of wiring leads.

16. The apparatus of claim 14, further comprising:
the distal end of the finger being spaced a first distance from the circuit component and the length of the finger extending to a second distance away from the circuit component as the length of the finger extends around the wiring lead, the second distance being larger than the first distance.

17. The apparatus of claim 14, further comprising:
the resilient finger having a base proximate the circuit component and the length of the finger extending from the base to the finger distal end, and the base having a cross-sectional area that is a largest cross-sectional area of the finger length.

18. The apparatus of claim 14, further comprising:
the length of the finger having a J-shape.

19. The apparatus of claim 14, further comprising:
a mounting clip removably attached to the circuit component and removably attached to the electric motor thereby removably attaching the circuit component to the electric motor; and,
the resilient finger being integral with the mounting clip.

20. The apparatus of claim 19, further comprising:
the resilient finger having a base that joins the finger to the mounting clip with the length of the finger extending from the base to the finger distal end, and the base having a cross-sectional area that is a largest cross-sectional area of the finger length.

21. The apparatus of claim 19, further comprising:
the length of the finger extending away from the mounting clip and then turning around and extending back toward the mounting clip as the length of the finger extends from the mounting clip to the finger distal end.

22. The apparatus of claim 21, further comprising:
a spacing between the finger distal end and the mounting clip spacing the finger distal end a first distance from the mounting clip and the length of the finger extending away from the mounting clip a second distance that is longer than the first distance.

23. The apparatus of claim 19, further comprising:
the distal end of the finger being spaced a first distance from the mounting clip and the length of the finger extending to a second distance away from the mounting clip as the length of the finger extends around the wiring lead, the second distance being larger than the first distance.

24. The apparatus of claim 19, further comprising:
the resilient finger being one of a pair of resilient fingers each having a same configuration and each being integral with the mounting clip.
